(19) United States
(12) Patent Application Publication
(10) Pub. No.: US 2007/0046339 A1
(43) Pub. Date: Mar. 1, 2007

(54) Output circuit

(75) Inventor: Kenji Satou, Miyazaki (JP)

Correspondence Address: NIXON PEABODY, LLP, 401 9TH STREET, NW, SUITE 900, WASHINGTON, DC, 20004-2128, US

(73) Assignee: OKI ELECTRIC INDUSTRY CO., LTD., Tokyo (JP)

(21) Appl. No.: 11/511,495

(22) Filed: Aug. 29, 2006

(30) Foreign Application Priority Data
Aug. 29, 2005 (JP) 2005-247019

(51) Int. Cl. H03B 1/00

(52) U.S. Cl. 327/112

(57) ABSTRACT

A drain of a NMOS 32 of a canceling circuit 30 is connected to an output node NO to set the source of the above NMOS32 to floating-state. Furthermore, the gate of the NMOS 32 is provided with a signal SB being inverted by an inverter 31. By the above operation, the NMOS 32 conducts the thoroughly opposite operation to one of the NMOS 22 of the driving circuit 20 and the under shoot caused by the above NMOS 22 is canceled by the over shoot caused by the NMOS 32. Consequently, the under shoot or the over shoot arising at the output node NO when the input signal IN is changed can be restrained.

### CROSS REFERENCE TO RELATED APPLICATION

A claim of priority under 35 U.S.C. §119 is made to Japanese Patent Application No. 2005-247019, filed Aug. 29, 2005, which is herein incorporated by reference in its entirety for all purposes.

### BACKGROUND OF THE INVENTION

Technical Field

The present invention relates to an output circuit for outputting three voltages corresponding to an input signal.

FIG. 2 is a view of circuit configuration diagram of a conventional output circuit for outputting three voltages (for example, VH=10V, VM=0, VL=−5V).

The above output circuit is used for a CCD driving device in, for example, a digital camera, etc., and consists of a decoding circuit 10 and a driving circuit 20.

The driving circuit 20 includes a P-channel MOS transistor (hereinafter referred to as “POMS”) 21 being connected between the voltage VH and an output node NO, an n-channel MOS transistor (hereinafter referred to as “NMOS”) 22 being connected between the output node NO and the voltage VM, and an NMOS 23 being connected between the output node NO and the voltage VL. A gate of the PMOS 21, a gate of the NMOS 22 and a gate of the NMOS 23 are provided with a signal SA, SB, SC by the decoding circuit 10, respectively.

The decoding circuit 10 generates the signals SA, SB and SC having the level of the VH or the VL for controlling the driving circuit 20 according to a value of the 2-bit input signal IN. For example, when the value of the input signal is “o”, the voltage VH is outputted as the signal SA and the voltage VL is outputted as the signal SB and SC to set all transistors in the driving circuit 20 to off-sate. Additionally, when the value of the input signal IN is “1”, the voltage VH is outputted as the signals SA and SC, and the voltage VL is outputted to the signal SB to set only the NMOS 23 to on-state. Furthermore, when the input signal IN is “2” or “3”, the signals SA, SB and SC for setting only the NMOS 22, and the PMOS 21, to on-state, respectively, are outputted.

Furthermore, the above decoding circuit 10 is configured to output the voltage VH to the signal SA, and the voltage VL to the signal SB, SC in order to set all transistors in the driving circuit 20 to off-state for a certain period when the value of the input signal IN is changed, and subsequently output the signal SA, SB, SC corresponding to the value of the input signal IN.

The operation thereof will be explained as below. For example, when the value of the input signal IN is “2”, the level of the signals SA, SB and SC from the decoding circuit 10 are the VH, VH and VL, respectively. By the above operation, the PMOS 21 and the NMOS 23 of the driving circuit 20 are set to off-state, and the NMOS 22 is set to on-state. Consequently, the output node NO is connected to the voltage VM by the NMOS 22, and the output voltage OUT of 0V is outputted from the above output node NO.

When the value of the input signal IN is changed to, “3” in the above state, the signal SA, SB, SC from the decoding circuit 10 are set to the voltage VH, VL, VL, respectively, for a certain period. By the above operation, the PMOS 21, NMOS 22 and NMOS 23 of the driving circuit 20 are all set to off-state, and then the output node NO is set to floating-state.

After a certain period, the signal SA from the decoding circuit 10 is changed to the voltage VL. By the above operation, the PMOS 21 of the driving circuit 20 is set to on-sate and the output node NO is connected to the voltage VH, then the output voltage OUT of 10V from the output node NO is outputted.

As described before, the decoding circuit 10 is configured not to output the signal SA,SB, SC corresponding to the changed value immediately after the input signal IN is changed but to set the output node NO to floating-state temporary and to output the corresponding signal SA, SB, SC, subsequently. By the above operation, there is no possibility that more than two transistors in the driving circuit 20 are set to on-sate simultaneously when the input signal IN is changed, therefore, a through current between voltage thereof can be prevented.

Such a technique is disclosed in Japanese Patent Laid-Open H09-186577

However, in the above mentioned circuit, the voltages between the sources and the gates of the transistor 21 to 23 for outputting are different each other when the output node NO is set to floating-state, therefore, there is a problem that an under shoot or an over shoot arise from the influence gate stray capacitance (parasitic capacitance).

FIG. 3 is a view of explanatory diagram of a porblem of FIG. 2. For example, when the value of the input signal IN is “2”, the signal SB is voltage VH (=10V) and the NMOS 22 is set to on-state, therefore, the output voltage OUT is set to the voltage VM (=0V).

At the above time point, when the value of the input signal IN is changed to “3”, the signal SB is changed to the voltage VL (=−5V) in order to set the output node NO to floating-state, the gate voltage of the NMOS 22 drops from 10V to −5V by the given time constant. At the time point when the gate voltage of the NMOS 22 falls to the threshold voltage VT of the above NMOS 22, the NMOS 22 becomes off-sate. By the above operation, the output node NO becomes floating-state.

Meanwhile, since the gate voltage of the NMOS 22 further continues to fall, the drain (i.e. Output node NO) voltage falls by the gate-drain stray capacitance of, the NMOS 22, then an under shoot arises.

Subsequently, the signal SA is changed to the voltage VL (=−5V), corresponding to the value of “3” of the input signal IN, and when the gate voltage of the PMOS 21 surpasses the threshold voltage, the above PMOS 21 is set to on-state. By the above operation, the output node NO rises to the voltage VH (=10V), however, since the voltage of the output node NO is decreased by the under shoot, there is a problem that the time to reach to the predetermined voltage VH is delayed.

On the contrary, in the case where the value of the input signal IN is changed from “3” to “2”, when the signal SA is set to the voltage VH and the PMOS 21 is changed to off-state, the drain voltage further rises due to the stray capacitance between the gate and the source of the above PMOS 21 and an over shoot arises. However, in the above case, the amount of the over shoot is slight.

The object of the present invention is restraining an under shoot or an over shoot at an floating-state of the output node and preventing the delay time.

### SUMMARY OF THE INVENTION

According to the present invention, an output circuit for outputting one of a first voltage, a second voltage, and a third voltage (where, the first voltage is larger than the second voltage, and the second voltage is larger than the third voltage.) corresponding to an input signal; consists of a driving circuit, a decoding circuit, and an canceling circuit. The driving circuit includes transistors being connected between the first voltage, the second voltage, and the third voltage and the output node, respectively, and being used as a first, a second, and a third switch controlled to on-state or off-state by a first, second, and a third control signal, respectively. The decoding circuit outputs the above first, the second, and third control signal. The first, second, and third control signal set one of the above first, second, and third transistor to be on-state and set the above transistors to off-state for a certain time when the above input signal is changed. Subsequently, the first, second, and third control signal set one of the above first, second, and third transistor to on-state corresponding to the changed input signal. The canceling circuit includes, a forth transistor and an inverter. The forth transistor has the same dimensions as the above second transistor and the drain thereof is connected to the above node and the source thereof is opened. The above inverter inverts the above second control signal and outputs the inverted signal to the gate of the above forth transistor.

According to the present invention, the drain of the forth transistor of the canceling circuit is connected to the output node, the source of the above forth transistor is set to floating-state, and the second control signal is inverted and given to the gate. By the above configuration, the forth transistor conducts the thoroughly opposite operation to the second transistor, and then the under shoot caused by the second transistor is canceled by the over shoot caused by the forth transistor. Consequently, there is an effect that an under shoot or over shoot at the output node is restrained when the input signal is changed and the increasing of the delay time can be prevented.

### BRIEF DESCRIPTION OF THE DRAWINGS

FIG. 1: A view of configuration diagram of an output circuit according to the first embodiment of the resent invention.

FIG. 2: A view of configuration diagram of an conventional output circuit.

FIG. 3: A view of explanatory diagram of the problem of FIG. 2.

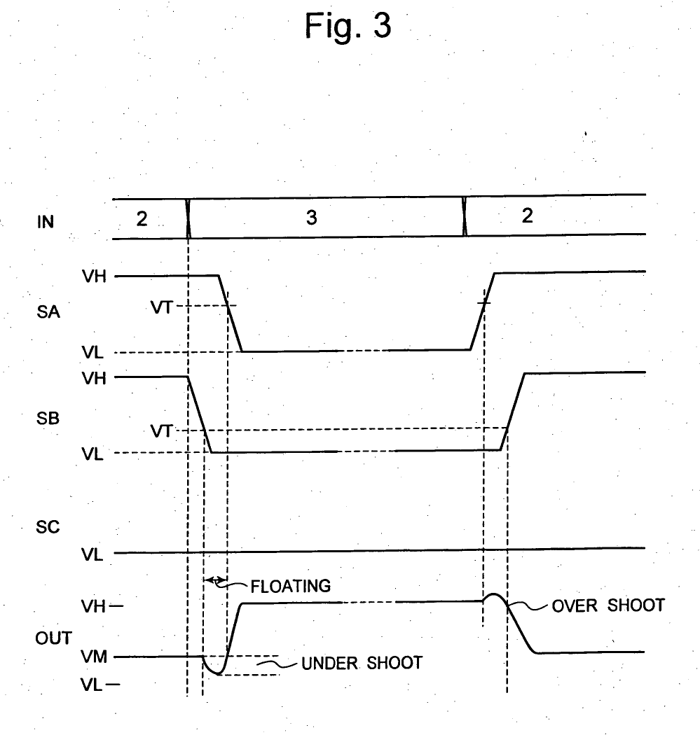

FIG. 4: A view of configuration diagram of an output circuit according to the second embodiment of the resent invention.

FIG. 5: A view of waveform diagram showing an example of the operation of FIG. 4.

### DETAILED DESCRIPTION OF THE PREFERRED EMBODIMENTS

An canceling circuit connected to the output node can be composed by a forth transistor being configured to be connected between the output node and the second voltage and have the smaller dimensions than the second transistor, and by a delay device being configured to delay the second control signal by a predetermined time and set the above transistor to on-state or off-sate.

The above mentioned and other objects and the novel advantage of the present invention will become more thoroughly clear by the following description of the preferred embodiments, referring to the attached drawings. However, the drawings are only for the explanations and do not limit the scope of the present invention.

### First Embodiment

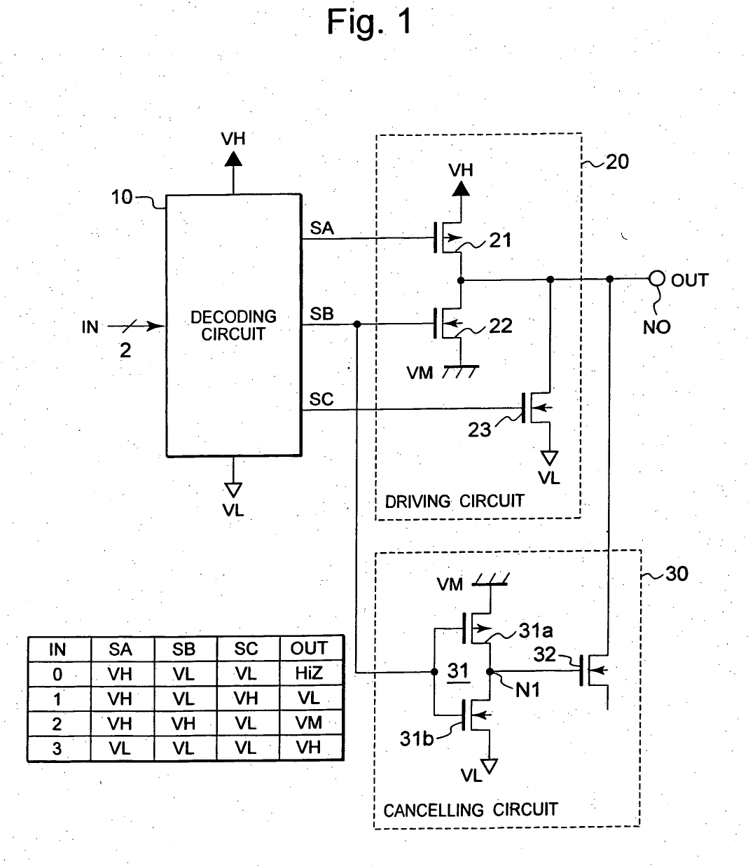

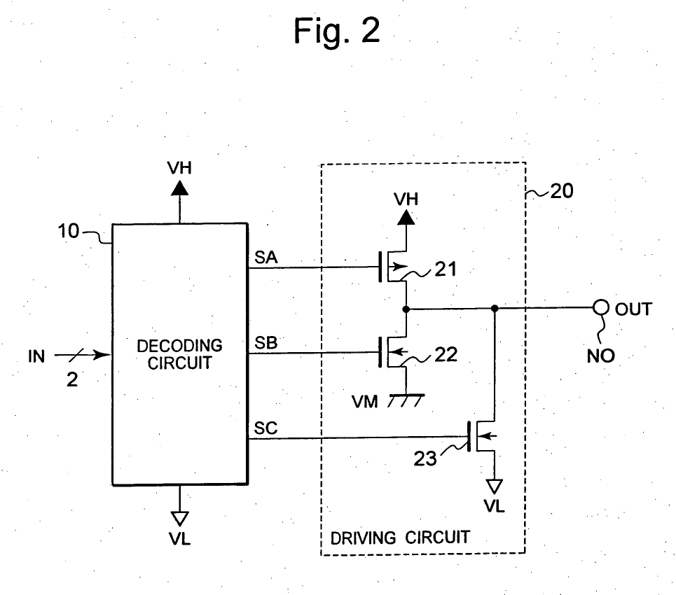

FIG. 1 is a view of configuration diagram of the first embodiment of the present invention. The identical elements to ones of FIG. 2 are given the same numerals as in FIG. 2.

The above output circuit is applied to a CCD driving device used for, for example, digital camera, etc., and is configured to output three voltages (for example, VH=10V, VM=0V VL=−5V) corresponding to the input signal IN, including a canceling circuit 30 for canceling an under shoot or an over shoot of the output node NO in addition to the decoding circuit 10 and the driving circuit 20 being the same as in FIG. 2.

The decoding circuit 10 generates the signals SA, SB and SC having the level of the voltage VH or the voltage VL in order to control the transistors of the driving circuit 20 for switching according to the 2 bit input signal IN. In the above decoding circuit 10, the voltage VH is outputted as the signal SA and the voltage VL is outputted as the signal SB, SC when the value of the input signal IN is “0”, the voltage VH is outputted as, the signal SA and SB, and the voltage VL is outputted as the signal SC when the value of the input signal IN is “2”, and the voltage VL is outputted to the signals SA, SB and SC when the input signal IN is “3”.

Furthermore, the above decoding circuit 10 outputs the voltage VH as the signal SA and output the voltage VL as the signal SB and SC for a certain time in order to set all the transistors for the switch in the driving circuit 20 to off-state, and to output thereafter the signals SA,SB and SC corresponding to the changed value of the input signal IN.

The driving circuit 20 includes the PMOS 21, the NMOS 22 and the NMOS 23 being connected between the output node NO and the voltage VH, VM and VL, respectively. The gate of the PMOS 21 is provided with the signal SA from the decoding circuit 10, the gate of the NMOS 22 is provided with the signal SB, and the gate of the NMOS 23 is provided with the signal SC.

The canceling circuit 30 consists of a PMOS 31a and the NMOS 31b composing the inverter 31, and the NMOS 32. That is, the gates of the PMOS 31a and the NMOS 31b are given the signal SB from the decoding circuit 10, and the sources of the above PMOS 31a and the NMOS 31b are connected to the voltage VM and the voltage VL, respectively. The drains of the PMOS 31a and the NMOS 31b are connected to a node N1, and the gate of the NMOS 32 is connected to the above node N1.

The drain of the NMOS 32 is connected to the output node NO and the source is floating-state. In addition, the dimensions of the gate width and the gate length of the NMOS 32 are set as the same as the dimensions of the above NMOS 22 in the decoding circuit 20.

The operation thereof will be explained as below. For example, when the input signal IN is “2”, the signal SB is set to the voltage VH (=10V), the NMOS 22 is set to on-state, and the output voltage OUT is set to the voltage VM (=0V).

At the above state, when the value of the input signal IN is changed to “3”, the signal SB is switched to the voltage VL (=−5V) in order to set the output node NO to floating-state, and then the gate voltage of the NMOS 22 falls from 10V to −5V by the given time constant. At the time point when the gate voltage of the NMOS 22 falls to the threshold voltage VT of the above NMOS 22, the NMOS 22 becomes off-state. By the above operation, the output node NO is set to floating-state.

At the above time, since the gate voltage of the NMOS 22 further continues to fall, the drain (i.e. the output node NO) voltage is forced to drop by the stray capacitance between the gate and source of the NMOS 22.

Meanwhile, when the signal SB is switched from the voltage VH to the voltage VL, the node N1 in the canceling circuit 30 rises from the voltage VH to the voltage VL. By the above operation, the drain (i.e. the output node NO) voltage of the NMOS 32 is forced to rise by the stray capacitance between the gate and the source of the NMOS 32.

In the floating state, the absolute voltage values provided the gate of the NMOS 22, 32 are approximately the same as each other and the directions are the opposite to each other. Additionally, the dimensions of the NMOS 22, 32 are set as the same as each other. Consequently, the voltage deviations by the stray capacitances between the gates and drains of the NMOS 22 and the PMOS 32 are canceled each other and then the under shoot or the over shoot thereof are restrained.

Subsequently, when the signal SA is hanged to the voltage VL (=−5V) and the gate voltage of the PMOS 21 surpasses the threshold, the PMOS 21 is set to on-sate. By the above operation, the output node NO rises to the voltage VH (=10V).

As explained before, the output circuit according to the first embodiment includes the canceling circuit 30 for providing the output node NO with the reverse voltage deviation in order to cancel the voltage deviation by the stray capacitance between the gate and source of the NMOS 22 in floating-state. By the above configuration, since the voltage deviations of the output node NO in floating state are canceled and the under shoot or the over shoot are restrained, the increase of the delay time can be prevented.

In addition, the present invention is not limited to the above first embodiment, there can be various modifications. The examples of the above modifications are as below.
(1) Three voltages are not limited to 10V, 0V, −5V but optional. For example, three voltages of VH=15V, VM=7V, VL=0V can be used therein.
(2) In the case where minus voltage of −5V, etc. is not used, a PMOS needs to be used instead of the NMOS 32 of the canceling circuit.

### Second Embodiment

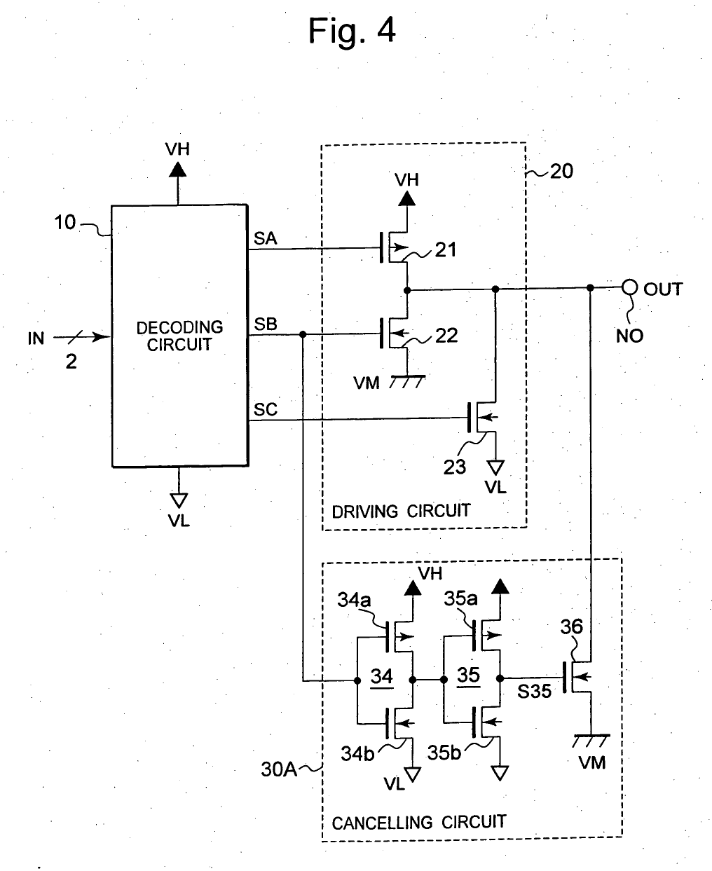

FIG. 4 is a view of configuration diagram of the output circuit according to the second embodiment. The identical elements to ones in FIG. 1 are given the same numerals as in FIG. 1. The output circuit thereof includes an canceling circuit 30A configured differently from the canceling circuit 30 in FIG. 1.

The canceling circuit 30A consists of two inverters 34 and 35 connected serially to delay the signal SB and an NMOS 36 having the gate given a signal S35 outputted from the above inverter 35. The inverter 34 consists of a PMOS 34a and a NMOS 34b, and the sources of the above PMOS 34a and the NMOS 34b are connected to the voltage VH, VL. Similarly, the inverter 35 consists of a PMOS 35a and a NMOS 35b and the sources thereof are connected to the voltage VH, VL, respectively.

A drain of NMOS 36 is connected to the output node NO and the source thereof is connected to the voltage VM. In addition, the dimensions of the above NMOS 36 are set to thoroughly smaller dimensions than the NMOS 22 in the driving circuit 20. Other configurations thereof are as the same as in FIG. 1.

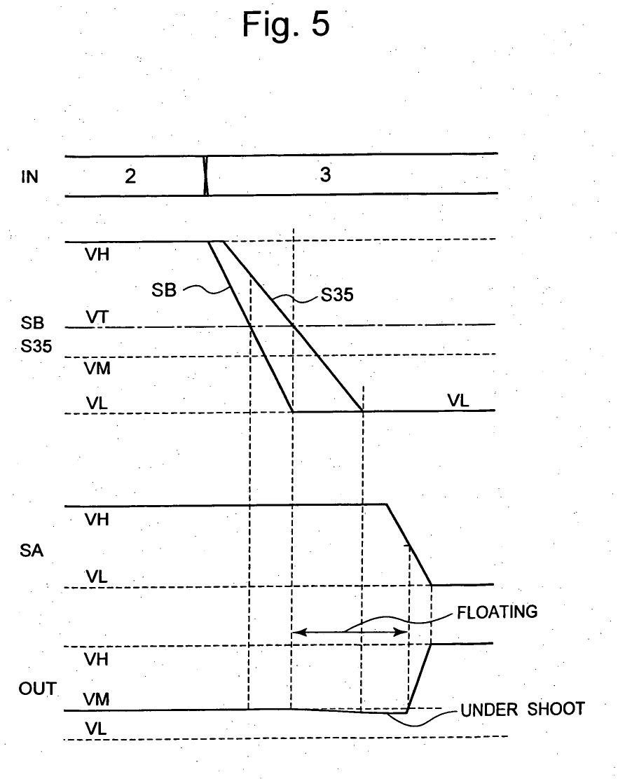

FIG. 5 is a view of wave form diagram showing one example of the operation in FIG. 4. The operation in FIG. 4, will be explained as below, referring to the above FIG. 5.

For example, when the value of the input signal IN is “2”, the signal SB is set to the voltage VH, and then both of the NMOS 22 of the driving circuit 20 and the NMOS 36 of the canceling circuit 30A are on-state.

At the above stage, in the case where the vale of the input signal IN is changed from “2” to “3” and the voltage of the output node NO is changed from VM (0V) to VH (10V), first, the signal SB is changed from VH to VL.

When the voltage of the signal SB falls to the threshold voltage VT of the NMOS 22 in the driving circuit 20, the above NMOS 22 becomes off-state. Thereafter, the gate voltage of the NMOS 22 further continues to fall, then the drain voltage becomes able to be fallen by the stray capacitance between the gate and the source of the NMOS 22. However, since the signal SB is delayed by the inverter 34 and 35 in the canceling circuit 30A and is given to the NMOS 36, at the above time point, the NMOS 36 is on-state. Consequently, the output node NO is connected to the voltage VM, and then no under shoot arises.

Secondly, the signal S35 outputted from the inverter 35 falls to the threshold voltage VT of the NMOS 36 behind the given time from the signal SB. By the above operation, the NMOS 36 becomes off-state behind the given time from the NMOS 22, and then the output node NO becomes floating state. At the time point thereof, an under shoot arises by the stray capacitance between the gates and the source of the NMOS 36, however, since the dimensions of the above NMOS 36 is set to sufficiently small ones, the amount of the under shoot becomes negligibly small.

Thereafter, the signal SA becomes the voltage VL (=−5V) and the gate voltage of the PMOS 21 surpasses the threshold voltage, then the above PMOS 21 becomes on-state. By the above operation, the output node NO rises to the voltage VH (=10V).

As explained before, the output circuit according to the second embodiment includes the canceling circuit 30A having the NMOS 36 of small dimensions for delaying by the predetermined time and changing the output node NO to floating-state. By the above configuration, immediately after the NMOS 22 of the large dimensions for switching in the driving circuit 20 becomes off-state, the output node NO does not become floating-state, then an under shoot caused by the above MNOS 22 can be prevented. Consequently, the amount of the under shoot can be restrained to be negligibly small, and then three is an advantage that the increase of the delay rime can be prevented.

The under shoot is arisen by the stray capacitance between the gate and the source of the NMOS 22. On the contrary, since the voltage of the output node NO is forced to rise to the voltage VM by applying a current directly to the voltage VM from the above output node NO when the NMOS 36 becomes on-sate, the dimensions of the NMOS 36 can be set to smaller dimensions compared with the NMOS 32 according to the first embodiment. Regarding the dimensions of the NMOS 36, approximately one tenth of the dimensions of the NMOS 32 can bring an adequate effect, even if there is a slight difference in the effect caused by the operation condition or the process thereof. Consequently, there is an advantage that the necessary area can be reduced compared with the first embodiment.

In addition, the present invention is not limited to the above second embodiment, and there can be various modifications similarly to the first embodiment.

What is claimed is:

1. An output circuit which outputs one of a first voltage, a second voltage, or a third voltage, where, the first voltage is larger than the second voltage, and the second voltage is larger than the third voltage, comprising;
a driving circuit which has a first transistor connected between the first voltage and an output node, a second transistor connected between the second voltage and the output node and a third transistor connected between the third voltage and the output node, wherein the first, second and third transistors controlled to be on-state or off-state by a first control signal, a second control signal, and a third control signal, respectively;
a decoding circuit being configured to set one of said first, said second, and said third transistor to on-state corresponding to said input signal, to set said first, said second, and said third transistor to off-state for a certain time when said input signal is changed, and to output thereafter said first control signal, said second control signal, and said third control signal for setting one of said first transistor, said second transistor, and said third transistor to on-state corresponding to said changed input signal; and
a canceling circuit being configured to include a forth transistor having the same dimensions as said second transistor, the drain being connected to said output node, and the source being opened, and to include an inverter for inverting said second control signal and providing the gate of said forth transistor with said inverted second control signal.

2. An output circuit for outputting one of a first voltage, a second voltage, or a third voltage (where, the first voltage is larger than the second voltage, and the second voltage is larger than the third voltage) comprising;
a driving circuit being configured to have transistors for a first switch, a second switch, and a third switch being connected between said first voltage, said second voltage, and said third voltage and an output node, respectively, and being controlled to be on-state or off-state by a first control signal, a second control signal, and a third control signal, respectively;
a decoding circuit being configured to set one of said first, said second, and said third transistor to on-state corresponding to said input signal, to set said first, said second, and said third transistor to off-state for a certain time when said input signal is changed, and to output thereafter said first control signal, said second control signal, and said third control signal for setting one of said first transistor, said second transistor, and said third transistor to on-state corresponding to said changed input signal; and
a canceling circuit being configured to include a forth transistor having smaller dimensions than said second transistor and being connected between said output node and said second voltage, and to include a delaying device for delaying said second control signal by a shorter time than said certain time and controlling said forth transistor to be on-state or off-state.

3. An output circuit comprising;
a decoder which outputs a control signal having a first voltage level or a second voltage level lower than said first voltage level in response to an input signal;
an output terminal;
a first transistor which provides said output terminal with said first voltage level based ojn said control signal;
a second transistor which provides said output terminal with a third voltage level of between said first voltage level and said second voltage level based on said control signal;
a third transistor which provides said output terminal with said second voltage level based on said control signal; and
a canceling circuit which provides said output terminal in response to said control signal given to said second transistor with a voltage for adjusting an under shoot of the output voltage level arising at said output terminal corresponding to a change of said control signal given to said second transistor from said first voltage level to said second voltage level.

4. The output circuit according to claim 3, wherein said canceling circuit includes a forth transistor having a gate given the inverted signal of the control signal given to said second transistor, a second terminal being connected to said output terminal.

5. The output terminal according to claim 4, wherein said second terminal of said forth transistor is floating-state.

6. The output circuit according to one of from claim 2, wherein said forth transistor has the same dimensions as said second transistor.
